(19) United States
(12) Patent Application Publication
(10) Pub. No.: US 2007/0215989 A1
(43) Pub. Date: Sep. 20, 2007

(54) Semiconductor chip assembly

(75) Inventors: Mu Shui Tsai, Kaohsiung City (TW); Li An Chen, Changhua (TW)

Correspondence Address: OLIFF & BERRIDGE, PLC, P.O. BOX 19928, ALEXANDRIA, VA, 22320, US

(73) Assignee: PROMOS TECHNOLOGIES INC., HSINCHU (TW)

(21) Appl. No.: 11/376,319

(22) Filed: Mar. 16, 2006

(51) Int. Cl. H01L 23/495

(52) U.S. Cl. 257/666

(57) ABSTRACT

A semiconductor chip assembly comprises a semiconductor chip including a first contact and a second contact positioned at a first side of the first contact, a first lead including an inner end, a second lead including a body positioned at a second side of the first lead and an inner segment positioned between the contacts of semiconductor chip and the inner end of the first lead, a first bonding wire connecting the first contact to the inner end of the first lead and a second bonding wire connecting the second contact and the inner segment of the second lead. The first side of the first contact is in the opposite direction to the second side of the first lead, and the first bonding wire and the second bonding wire do not cross each other. Preferably, the second lead further includes a middle portion between the body and the inner segment, or the second lead is L-shaped.

### BACKGROUND OF THE INVENTION

(A) Field of the Invention

The present invention relates to a semiconductor chip assembly, and more particularly, to a semiconductor chip assembly incorporating one lead component including one lead having an inner segment extending to a region between an inner end of another lead and a contact of a semiconductor chip to prevent bonding wires from crossing.

(B) Description of the Related Art

Wire bonding is the process of making electrical connections in semiconductor components by means of electrically conductive wires, typically wires with a diameter of from 12 microns to 500 microns. As technology advances, the dimensions of integrated circuit packages continue to decrease, requiring corresponding decreases in integrated circuit chips. The decrease in the physical size of integrated circuit chips necessitates a similar reduction in the size of lead frames. This coincides with the leads of the lead frame approaching smaller and smaller dimensions, which increases the likelihood of electrical contact between bonding wires and other leads of the lead frame.

In a conventional lead frame, the leads are arranged in a radial pattern away from the bond pad array (contacts) of the semiconductor chip. The semiconductor chip is wire bonded to leads of the lead frame by bonding wires such that they do not cross each other to prevent the wires from contacting during the subsequent encapsulating process. In other words, the conventional lead frame does not allow the electrical signal to propagate from contacts of the semiconductor chip to the lead of the lead frame in an exchange manner.

### SUMMARY OF THE INVENTION

The primary objective of the present invention is to provide a semiconductor chip assembly incorporating one lead component including one lead having an inner segment extending to a region between an inner end of another lead and a contact of a semiconductor chip, which allows the electrical signal to propagate from the contacts of the semiconductor chip to the leads of the lead frame in an exchange manner via the bonding wires without crossing.

In order to achieve the above-mentioned objective and avoid the problems of the prior art, one embodiment of the present invention discloses a semiconductor chip assembly comprising a semiconductor chip including a first contact and a second contact positioned at a first side of the first contact, a first lead including an inner end, a second lead including a body positioned at a second side of the first lead and an inner segment positioned between the second contact of the semiconductor chip and the inner end of the first lead, a first bonding wire connecting the first contact and the inner end of the first lead and a second bonding wire connecting the second contact and the inner segment of the second lead. The first side of the first contact is in the opposite direction to the second side of the first lead, and the first bonding wire and the second bonding wire do not cross each other. Preferably, the second lead further includes a middle portion between the body and the inner segment, or the second lead is L-shaped.

The semiconductor chip assembly may further comprise a third lead positioned between the first lead and the body of the second lead and a third bonding wire connecting the third lead and a third contact positioned at a second side of the first contact. The second side of the first contact is in the opposite direction to the first side of the first contact. Further, the semiconductor chip assembly may comprise a third lead positioned at a first side of the first lead being in the opposite direction to the second side of the first lead and a third bonding wire connecting the third lead and a third contact positioned at a first side of the first contact, wherein the second contact is positioned between the first contact and the third contact, and the inner segment of the second lead extends to a region between the third lead and the third contact of the semiconductor chip.

Conventional lead frame design has the leads arranged in a radial pattern away from the semiconductor chip, which makes the electrical signal impossible to propagate from contacts of the semiconductor chip to the leads of the lead frame in an exchange manner without crossing of the bonding wires. In contrast, the extension of the inner segment of the second lead to a region between the inner end of the first lead and the contact of the semiconductor chip allows the electrical signal to propagate from the contacts of the semiconductor chip to the leads of the lead frame in an exchange manner via the bonding wires without crossing the bonding wires according to the present invention.

### BRIEF DESCRIPTION OF THE DRAWINGS

The objectives and advantages of the present invention will become apparent upon reading the following description and upon reference to the accompanying drawings in which:

FIG. 1 illustrates a semiconductor chip assembly according to a first embodiment of the present invention;

FIG. 2(a) and FIG. 2(b) illustrate a semiconductor chip assembly according to a second embodiment of the present invention;

FIG. 3(a) and FIG. 3(b) illustrate a semiconductor chip assembly according to a third embodiment of the present invention; and

FIG. 4(a) and FIG. 4(b) illustrate a semiconductor chip assembly according to a fourth embodiment of the present invention.

### DETAILED DESCRIPTION OF THE INVENTION

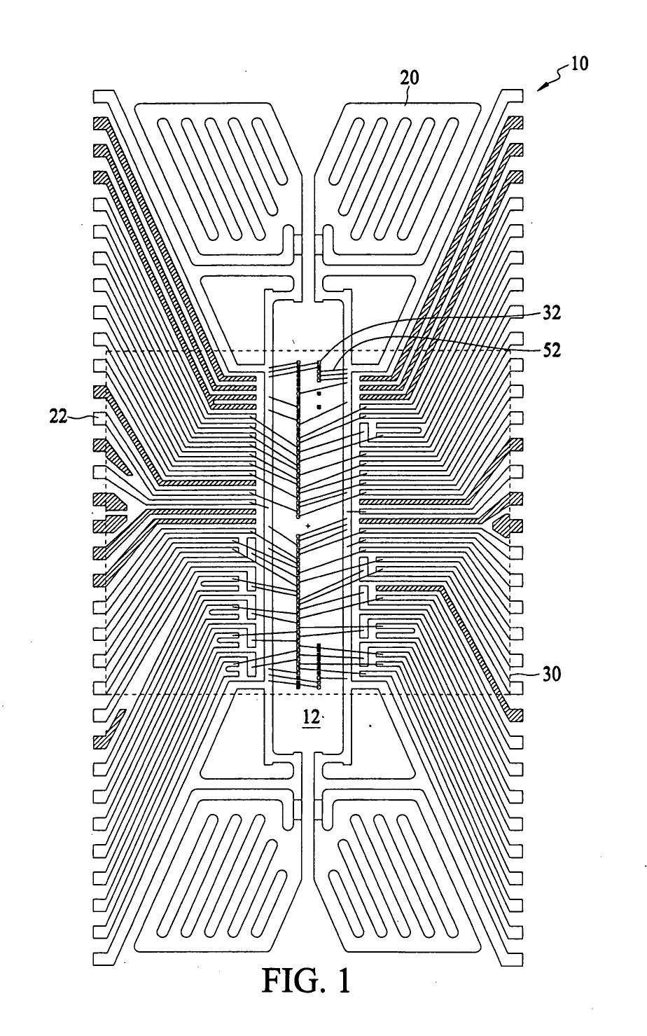

FIG. 1 illustrates a semiconductor chip assembly 10 according to a first embodiment of the present invention. The semiconductor chip assembly 10 comprises a lead frame 20 having an opening 12, a semiconductor chip 30 with a plurality of contacts 32, i.e., pad array positioned in the opening 12, a plurality of bonding wires 52, each connecting one of the contacts 32 of the semiconductor chip 30 to one of the leads 22 of the lead frame 20.

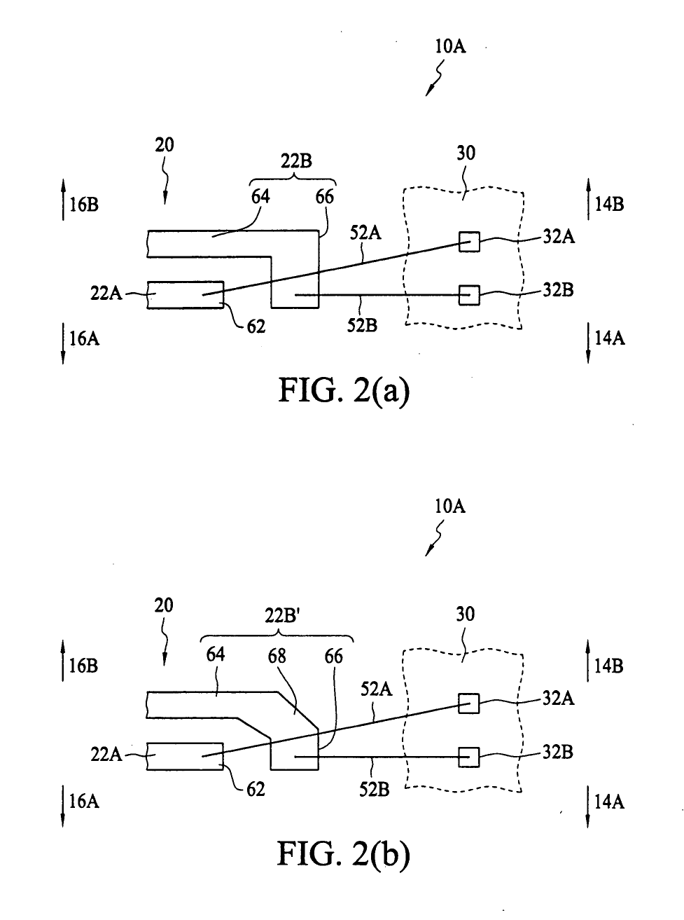

FIG. 2(a) and FIG. 2(b) illustrate a semiconductor chip assembly 10A according to second embodiment of the present invention. The semiconductor chip 30 comprises a first contact 32A and a second contact 32B positioned at a first side 14A of the first contact 32A. The lead frame 20 comprises a first lead 22A including an inner end 62, and a second lead 22B including a body 64 positioned at a second side 16B of the first lead 22A and an inner segment 66 positioned between the second contact 32B of the semiconductor chip 30 and the inner end 62 of the first lead 22A. A first bonding wire 52A is used to connect the first contact 32A and the inner end 62 of the first lead 22A, and a second bonding wire 52B is used to connect the second contact 32B and the inner segment 66 of the second lead 22B.

Particularly, the second side 16B of the first lead 22A is in the opposite direction to the first side 14A of the first contact 32A, the first bonding wire 52A and the second bonding wire 52B do not cross each other, and the second lead 22B is L-shaped. Alternatively, a middle portion 68 may be incorporated between the body 64 and the inner segment 66 to form a second lead 22B′, as shown in FIG. 2(b).

Since the inner segment 66 of the second lead 22B extends to a region between the inner end 62 of the first lead 22A and the second contact 32B of the semiconductor chip 30, the electrical signal can propagate in an exchange manner without crossing the bonding wires 52A and 52B, i.e., the electrical signal can propagate from the first contact 32A at the top of the semiconductor chip 30 to the first lead 22A at the bottom of the lead frame 20, and from the second contact 32B at the bottom of the semiconductor chip 30 to the second lead 22B at the top of the lead frame 20.

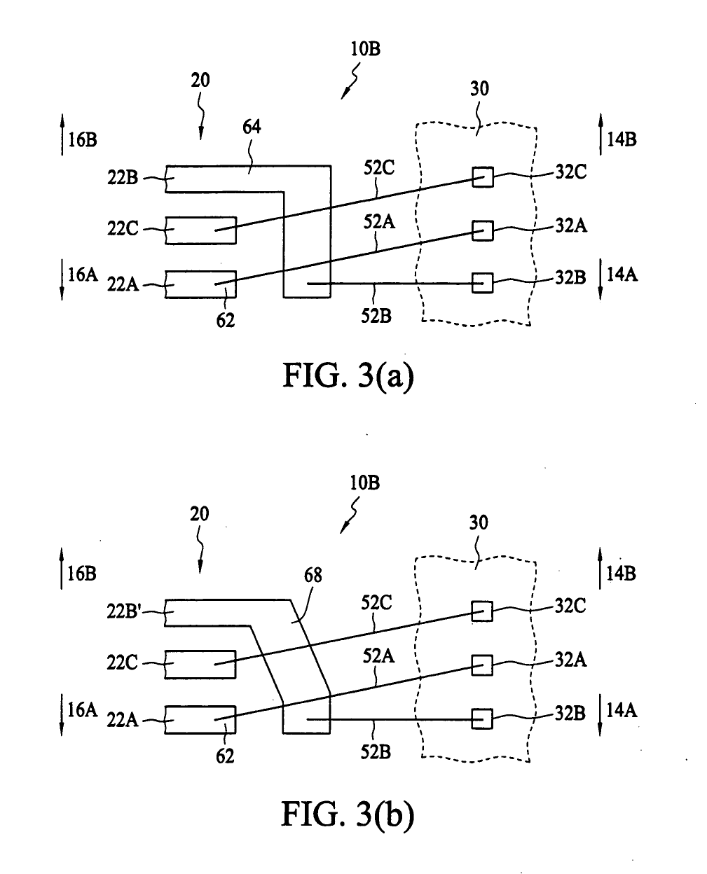

FIG. 3(a) and FIG. 3(b) illustrate a semiconductor chip assembly 10B according to third embodiment of the present invention. In comparison with the semiconductor chip assembly 10A, the semiconductor chip assembly 10B further comprises a third lead 22C positioned between the first lead 22A and the body 64 of the second lead 22B, and a third bonding wire 52C is further used to connect the third lead 22C and a third contact 32C positioned at a second side 14B of the first contact 32A, which is in the same direction of the second side 16B of the first lead 22A, and therefore is the opposite direction to the first side 14A of the first contact 32A. Similarly, the second lead 22B′ with a middle portion 68 can be used in place of the second lead 22B, as shown in FIG. 3(b).

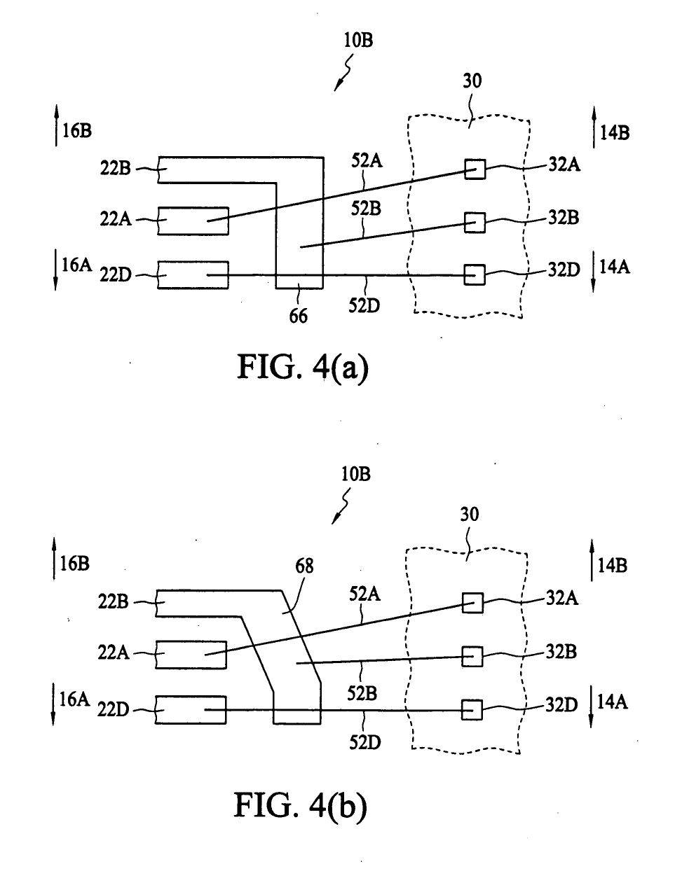

FIG. 4(a) and FIG. 4(b) illustrate a semiconductor chip assembly 10C according to fourth embodiment of the present invention. In comparison with the semiconductor chip assembly 10A, the semiconductor chip assembly 10C further comprise a third lead 22D positioned at a first side 16A of the first lead 22A, which is in the opposite direction to the second side 16B of the first lead 22A. A third bonding wire 52D is used to connect the third lead 22D and a third contact 32D positioned at a first side 14A of the first contact 32A, wherein the second contact 32B is positioned between the first contact 32A and the third contact 32C. Particularly, the inner segment 66 of the second lead 22B may extend to a region between the third lead 22D and the third contact 32D of the semiconductor chip 30. Similarly, the second lead 22B′ with a middle portion 68 as shown in FIG. 4(b) can be used in place of the second lead 22B.

Conventional lead frame design has the leads arranged in a radial pattern away from the semiconductor chip, and it makes the electrical signal impossible to propagate from contacts of the semiconductor chip to the lead of the lead frame in an exchange manner without signal crossing of the bonding wires. In contrast, the extension of the inner segment 66 of the second lead 22B and 22B′ to a region between the inner end 62 of the first lead 22A and the contact 32 of the semiconductor chip 30 allows the electrical signal to propagate from contacts 32 of the semiconductor chip 30 to the leads 22 of the lead frame 20 via the bonding wires 52 in an exchanging manner without crossing of the bonding wires 52 according to the present invention.

The above-described embodiments of the present invention are intended to be illustrative only. Numerous alternative embodiments may be devised by those skilled in the art without departing from the scope of the following claims.

What is claimed is:

1. A semiconductor chip assembly, comprising:
a semiconductor chip including a first contact and a second contact positioned at a first side of the first contact:
a first lead including an inner end;
a second lead including a body positioned at a second side of the first lead and an inner segment positioned between the second contact of the semiconductor chip and the inner end of the first lead, the first side of the first contact being in the opposite direction to the second side of the first lead;
a first bonding wire connecting the first contact and the inner end of the first lead; and
a second bonding wire connecting the second contact and the inner segment of the second lead.

2. The semiconductor chip assembly of claim 1, wherein the first bonding wire and the second bonding wire do not cross each other.

3. The semiconductor chip assembly of claim 1, wherein the second lead further includes a middle portion between the body and the inner segment.

4. The semiconductor chip assembly of claim 1, wherein the second lead is L-shaped.

5. The semiconductor chip assembly of claim 1, further comprising:
a third lead positioned between the first lead and the body of the second lead;
a third contact positioned at a second side of the first contact, the second side of the first contact being in the opposite direction to the first side of the first contact; and
a third bonding wire connecting the third lead and the third contact.

6. The semiconductor chip assembly of claim 1, further comprising:
a third lead positioned at a first side of the first lead being in the opposite direction to the second side of the first lead;
a third contact positioned at the first side of the first contact; and
a third bonding wire connecting the third lead and the third contact.

7. The semiconductor chip assembly of claim 6, wherein the second contact is positioned between the first contact and the third contact of the semiconductor chip.

8. The semiconductor chip assembly of claim 6, wherein the inner segment of the second lead extends to a region between the third lead and the third contact of the semiconductor chip.

9. A lead component for a semiconductor chip including a first contact and a second contact positioned at a first side of the first contact, the lead component comprising:
a first lead including an inner end; and
a second lead including a body positioned at a second side of the first lead and an inner segment positioned between the second contact of the semiconductor chip and the inner end of the first lead, the first side of the first contact being in the opposite direction to the second side of the first lead.

10. The lead component of claim 9, wherein the second lead further includes a middle portion between the body and the inner segment.

11. The lead component of claim 9, wherein the second lead is L-shaped.

12. The lead component of claim 9, further comprising a third lead positioned between the first lead and the body of the second lead.

13. The lead component of claim 9, further comprising a third lead positioned at a first side of the first lead being in the opposite direction to the second side of the first lead, and the inner segment of the second lead extending to a region between the third lead and the third contact of the semiconductor chip.
